(19) United States
(12) Patent Application Publication
(10) Pub. No.: US 2018/0182662 A1
(43) Pub. Date: Jun. 28, 2018

(54) METHOD FOR PREPARING SUBSTRATE WITH CARRIER TRAPPING CENTER

(71) Applicant: Shanghai Simgui Tehcnology Co., Ltd., Shanghai (CN)

(72) Inventors: Xing WEI, Shanghai (CN); Yongwei CHEN, Shanghai (CN); Meng CHEN, Shanghai (CN); Guoxing CHEN, Shanghai (CN); Lu FEI, Shanghai (CN); Xi WANG, Shanghai (CN)

(73) Assignee: Shanghai Simgui Tehcnology Co., Ltd., Shanghai (CN)

(21) Appl. No.: 15/904,129

(22) Filed: Feb. 23, 2018

(30) Foreign Application Priority Data
Dec. 27, 2016 (CN) 201611227767.3

(51) Int. Cl. H01L 21/762; H01L 21/265; H01L 21/324; H01L 29/06

(52) U.S. Cl. CPC H01L 21/76254; H01L 29/0603; H01L 21/324; H01L 21/26533

(57) ABSTRACT

The present disclosure provides a method for preparing a substrate with a carrier trapping center. The method includes: injecting bubbling ions into the semiconductor substrate to form a splitting layer, and injecting modified ions into the insulating layer to form a nano cluster; providing a supporting substrate; bonding the supporting substrate to the semiconductor substrate by using the insulating layer as an intermediate layer; performing a first heat treatment for the bonded substrate such that a splitting layer is formed at the position where the bubbling ions are injected, and causing the semiconductor substrate to split at the position of the splitting layer; thinning a splitting surface of the split semiconductor substrate; and performing a second heat treatment for the thinned semiconductor substrate to consolidate the bonding interface and form the nano cluster at the position where the modified ions are injected.

The present application is based on and claims the priority to Chinese patent application No. CN201611227767.3, filed on Dec. 27, 2016, which is incorporated by reference herein in its entirety.

### TECHNICAL FIELD

The present disclosure relates to the field of semiconductor materials, and in particular, relates to a method for preparing a substrate with a carrier trapping center.

### BACKGROUND

In the prior art, a typical substrate structure with an insulating buried layer includes three layers, which are sequentially a supporting layer, an insulating layer on the surface of the supporting layer, and a device layer on the surface of the insulating layer. In some application scenarios, to prevent carriers from being excited by high-energy rays and thus migrating from the exterior of the substrate, a layer of carrier trapping center needs to be introduced to the substrate to trap these carriers, so as to improve the electrical properties of the electronic devices in the device layer. However, in practice, to introduce the carrier trapping center, extra modified ions need to be introduced by means of injection and the like, and thus the process is very complicated. The complicated preparation process causes damages to the lattice of the device layer, and thus lowers the electrical properties of the electronic devices in the device layer. Therefore, how to optimize the preparation process to reduce the damages caused to the lattice of the device layer is a problem to be urgently addressed in the prior art.

### SUMMARY

The technical problem to be solved by the present disclosure is to provide a method for preparing a substrate with a carrier trapping center, which improves crystal quality of a device layer.

A method for preparing a substrate with a carrier trapping center includes: injecting bubbling ions into the semiconductor substrate to form a splitting layer, and injecting modified ions into the insulating layer to form a nano cluster; providing a supporting substrate; bonding the supporting substrate to the semiconductor substrate by using the insulating layer as an intermediate layer; performing a first heat treatment for the bonded substrate such that a splitting layer is formed at the position where the bubbling ions are injected, and causing the semiconductor substrate to split at the position of the splitting layer; thinning a splitting surface of the split semiconductor substrate; and performing a second heat treatment for the thinned semiconductor substrate to consolidate the bonding interface and form the nano cluster at the position where the modified ions are injected.

Optionally, through the thinning step, the thickness of the splitting surface is reduced by 10 to 150 nm.

Optionally, the second heat treatment further includes: performing a first annealing step, wherein the first annealing step is practiced in an oxygen-containing atmosphere, and an oxidation layer is formed on a surface of the substrate through the annealing step, the oxidation layer having a thickness of greater than 40 nm; and performing a second annealing step upon the first annealing step, wherein a temperature of the second annealing step is higher than that of the first annealing step. The first annealing step is performed within a temperature range of 900° C. to 1350° C. The second annealing step is performed within a temperature range of 1000° C. to 1350° C.

Optionally, the first annealing step is practiced in a dry oxygen environment. Optionally, the second annealing step is practiced in an oxygen-free environment.

Optionally, the modified ions are derived from one of chemical elements forming the insulating layer, or the modified ions are derived from a congener in chemical elements forming the insulating layer. The insulating layer is made from silicon dioxide, and the modified ions are silicon or germanium ions.

Optionally, the first heat treatment is performed within a temperature range of 300° C. to 800° C.

Optionally, the surface of the supporting substrate for bonding is provided with an oxidation layer.

The present disclosure is advantageous in that upon splitting, dislocations on a splitting surface upon thinning are removed, and then a nano cluster is formed via annealing. The annealing process forming the nano cluster takes a long time and is carried out in at a high temperature, and the surface is split in advance to remove the dislocations, thereby preventing the dislocations from growing to the entire device layer at the high temperature, and improving crystal quality of a resulted device layer.

### BRIEF DESCRIPTION OF THE DRAWINGS

FIG. 1 is a schematic flowchart of a method for preparing a semiconductor substrate with a carrier trapping center according to an aspect of the present disclosure; and

FIG. 2A illustrates the semiconductor substrate corresponding to a step in a schematic process diagram according to an aspect of the present disclosure.

FIG. 2B illustrates the semiconductor substrate corresponding to a step in a schematic process diagram according to an aspect of the present disclosure.

FIG. 2C illustrates the semiconductor substrate corresponding to a step in a schematic process diagram according to an aspect of the present disclosure.

FIG. 2D illustrates the semiconductor substrate corresponding to a step in a schematic process diagram according to an aspect of the present disclosure.

FIG. 2E illustrates the semiconductor substrate corresponding to a step in a schematic process diagram according to an aspect of the present disclosure.

FIG. 2F illustrates the semiconductor substrate corresponding to a step in a schematic process diagram according to an aspect of the present disclosure.

FIG. 2G illustrates the semiconductor substrate corresponding to a step in a schematic process diagram according to an aspect of the present disclosure.

### DETAILED DESCRIPTION

Specific embodiments illustrating a method for preparing a semiconductor substrate with a carrier trapping center according to the present disclosure are described in detail with reference to the accompanying drawings.

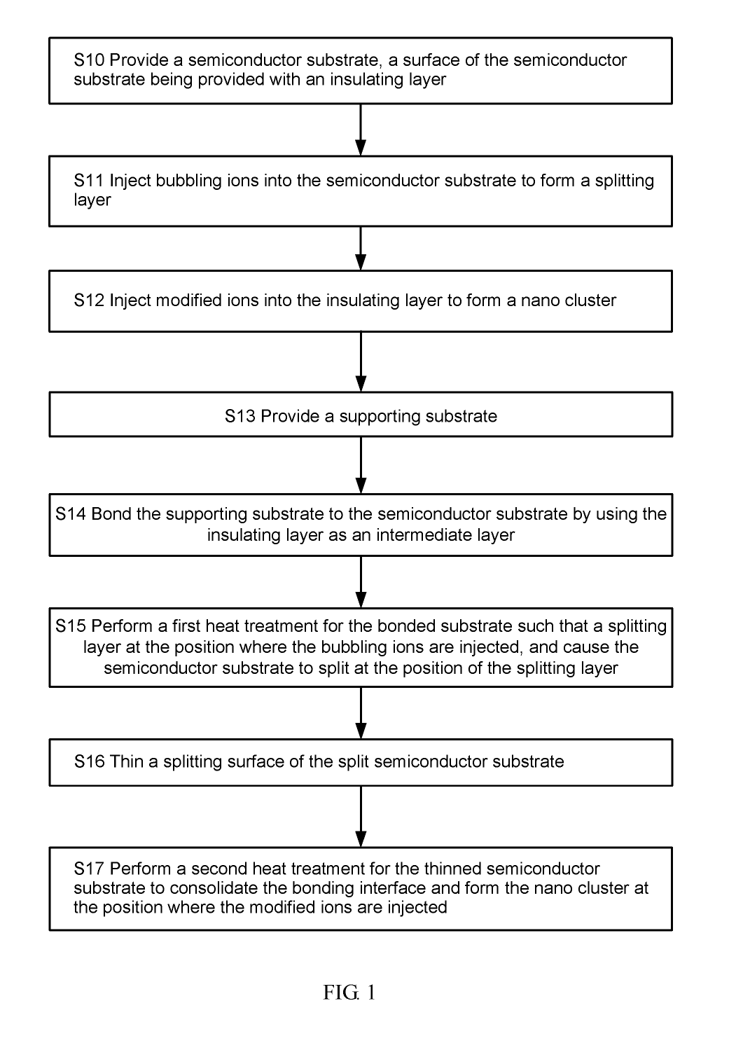

FIG. 1 is a schematic flowchart of a method for preparing a semiconductor substrate with a carrier trapping center according to a specific embodiment of the present disclosure. The method includes: step S10 providing a semiconductor substrate, a surface of the semiconductor substrate being provided with an insulating layer; step S11 injecting bubbling ions into the semiconductor substrate to form a splitting layer; step S12 injecting modified ions into the insulating layer to form a nano cluster; step S13 providing a supporting substrate; step S14 bonding the supporting substrate to the semiconductor substrate by using the insulating layer as an intermediate layer; step S15 performing a first heat treatment for the bonded substrate such that a splitting layer at the position where the bubbling ions are injected, and causing the semiconductor substrate to split at the position of the splitting layer; step S16 thinning a splitting surface of the split semiconductor substrate; and step S17 performing a second heat treatment for the thinned semiconductor substrate to consolidate the bonding interface and form the nano cluster at the position where the modified ions are injected.

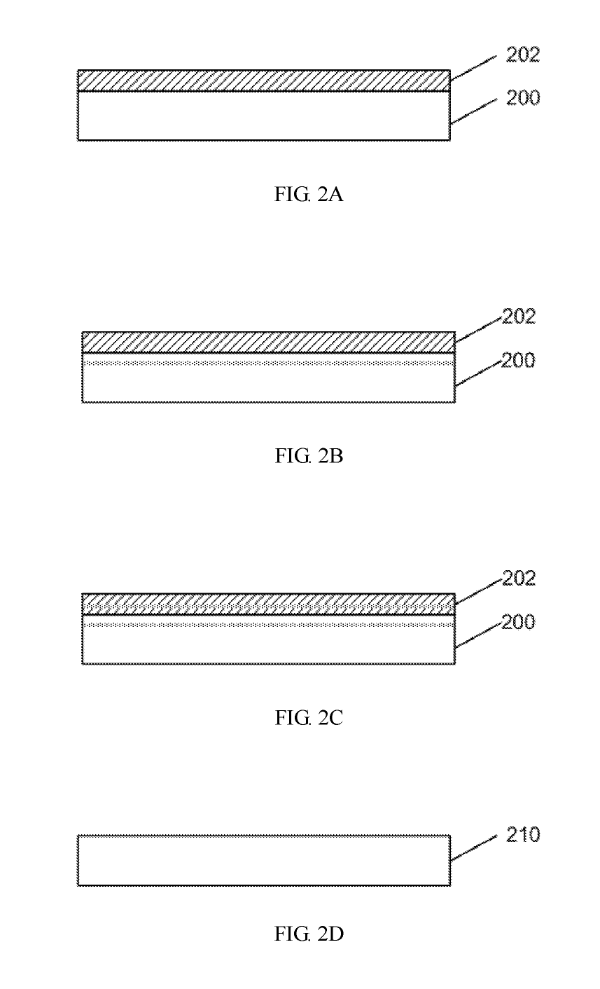

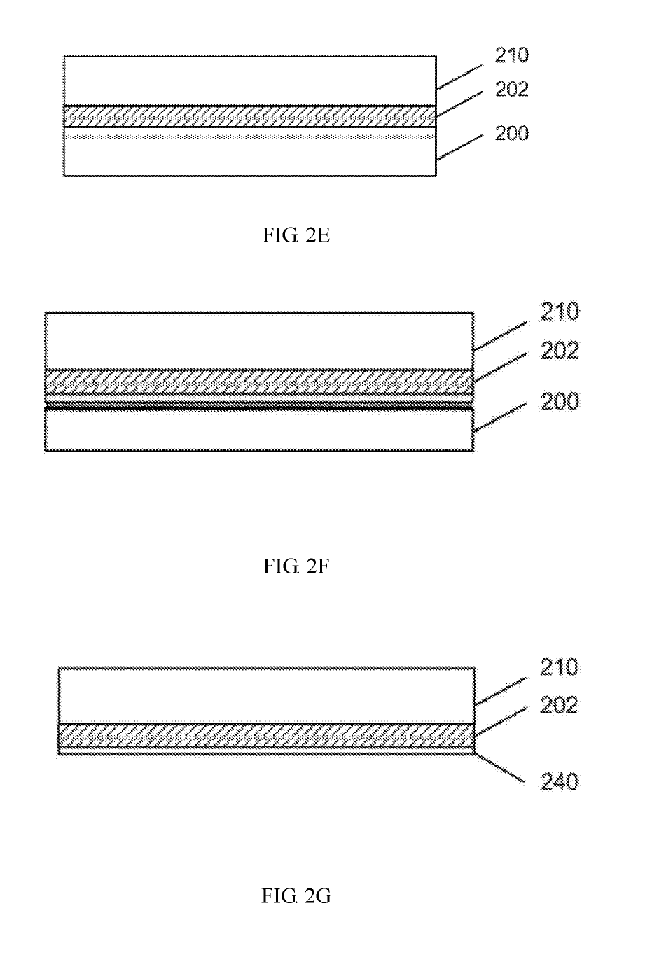

FIG. 2A to FIG. 2C are schematic process diagrams according to a specific embodiment of the present disclosure.

As illustrated in FIG. 2A, referring to step S10, a semiconductor substrate 200 is provided, wherein a surface of the semiconductor substrate 200 is provided with an insulating layer 202. In this specific embodiment, the semiconductor substrate 200 is made from silicon, and the insulating layer 202 is made from silicon dioxide. In another specific embodiment, the semiconductor substrate 200 may be made from germanium-silicon, germanium or a compound semiconductor or the like, and the insulating layer 202 may be made form silicon nitride, silicon oxynitride, germanium-silicon oxide, or another commonly used insulating material.

As illustrated in FIG. 2B, referring to step S11, bubbling ions are injected into the semiconductor substrate 200 to form a splitting layer. The bubbling ions may be argon ions, nitrogen ions, or a mixture thereof. After the above ions are injected, a bubbling layer is formed at a high temperature, such that the semiconductor substrate 200 is subjected to cracking or splitting. With respect to H ions, generally the injected energy is 5 keV to 500 keV, and the injection amount is 1×10¹⁵ to 3×10¹⁷ cm⁻².

As illustrated in FIG. 2C, referring to step S12, modified ions are injected into the insulating layer 102 to form a nano cluster. In this specific embodiment, the modified ions are derived from by silicon, such that a silicon-enriched layer is formed in the insulating layer 202, and thus a silicon-enriched nano cluster is formed upon a further heat treatment. In another specific embodiment, the modified ions may be derived from one of chemical elements forming the insulating layer, for example, germanium or silicon is injected into germanium-silicon oxide. Alternatively, the modified ions may also be derived from a congener in chemical elements forming the insulating layer, for example, germanium is injected into silicon oxide. Since the congeners have approximate chemical properties, a nano cluster that is capable of effectively trapping carriers may also be formed. With respect to silicon ions, generally the injected energy is 5 keV to 500 keV, and the injection amount is 1×10¹⁵ to 3×10¹⁷ cm⁻², and the injection position is preferably proximate to the interface between the insulating layer 202 and the semiconductor substrate 200.

The sequence for performing step S11 and step S12 is not definite.

As illustrated in FIG. 2D, referring to step S13, a supporting substrate 210 is provided. In this specific embodiment, the supporting substrate 210 may be made from silicon. In another specific embodiment, the supporting substrate 210 may be made from germanium-silicon, germanium or a compound semiconductor or the like, or sapphire, silicon carbide and the like commonly used substrate material.

As illustrated in FIG. 2E, referring to step S14, the supporting substrate 210 is bonded to the semiconductor substrate 200 by using the insulating layer 202 as an intermediate layer. In this step, common bonding or plasma-assisting bonding is employed. In the above step, the surface of the supporting substrate 210 for bonding may also be provided with an oxidation layer, and the oxidation layer and the insulating layer 202 form an insulating buried layer in the bonding step.

As illustrated in FIG. 2F, referring to step S15, a first heat treatment is performed for the bonded substrate such that a splitting layer at the position where the bubbling ions are injected, and the semiconductor substrate is caused to split at the position of the splitting layer. This step is preferably performed within a temperature range of 300° C. to 800° C.

As illustrated in FIG. 2G referring to step S16, a splitting surface of the split semiconductor substrate is thinned. In FIG. 2G a part of the supporting substrate 213 reserved in the bonded substrate after splitting forms a device layer 240, wherein the device layer 240 may be configured to prepare a semiconductor device. The nano cluster formed at the position where the modified ions are injected may trap the carriers in the device layer 240. In this step, with respect to thinning, chemical mechanical polishing or mechanical grinding may be employed, and the mechanical grinding is preferably employed and then thinning is continued by employing the chemical mechanical polishing to obtain a flat surface. In this step, the thickness of the splitting surface is reduced by 10 to 150 nm. The thinning may remove dislocations formed by the splitting step in the interface, and prevent the dislocations from diffusing and growing to the entire device layer 240 during the annealing process which thus lowers crystal quality of the device layer 240.

Referring to step S16, a second heat treatment is performed for the bonded substrate to consolidate the bonding interface and form the nano cluster at the position where the modified ions are injected. In this step, the heat treatment is preferably performed within a temperature range of 900° C. to 1350° C. This step employs two heat treatment processes. In the first heat treatment process, the second heat treatment process is performed upon splitting by the first heat treatment and promotes formation of the nano cluster, and further consolidates the bonding interface, such that the process steps are simplified. Upon splitting, the semiconductor layer, that is, the device layer 240, bonded to the insulating layer 202 may be further polished.

To improve the capability of the nano cluster in trapping carriers, a preferred specific embodiment involves two steps in the heat treatment: performing a first annealing step, wherein the first annealing step is practiced in an oxygen-containing atmosphere, and an oxidation layer is formed on a surface of the substrate through the annealing step, the oxidation layer having a thickness of greater than 40 nm; and performing a second annealing step, wherein a temperature of the second annealing step is higher than that of the first annealing step.

Specifically, the first annealing step is preferably performed within a temperature range of 900° C. to 1350° C., and is preferably practiced in a wet oxygen environment. In this way, an oxidation protection layer having a thickness of greater than 40 nm may be quickly formed on the surface of the substrate, wherein the oxidation protection layer may prevent the oxygen element from diffusing to the substrate during the annealing process and bonding to the modified ions, and reducing density of the nano cluster. In addition, this step may also restore or eliminate injection damages in the semiconductor substrate 200, such that a large number of interstitial silicon atoms in the semiconductor substrate 200 are recombined and released, thereby preventing dislocations and defects. The second annealing step is preferably performed within a temperature range of 1000° C. to 1350° C., and is preferably practiced in an oxygen-free environment, for example, in an argon environment. The annealing at an even higher temperature causes the injected silicon atoms to aggregate and form a stable nano cluster, and meanwhile further restores integrity of the lattice and reduces dislocation density. Further, the oxygen-free environment prevents the oxygen atom from entering the substrate and bonding to the modified ions. Such bonding may reduce the density of the nano cluster, and thus affect the trapping efficiency of the carrier trapping center.

In the above technical solution, upon splitting, dislocations on the splitting surface upon thinning are removed, and then the nano cluster is formed via annealing. The annealing process forming the nano cluster takes a long time and is carried out in at a high temperature, and the surface is split in advance to remove the dislocations, thereby preventing the dislocations from growing to the entire device layer at the high temperature, and improving crystal quality of a resulted device layer.

Described above are preferred examples of the present disclosure. It should be noted that persons of ordinary skill in the art may derive other improvements or polishments without departing from the principles of the present disclosure. Such improvements and polishments shall be deemed as falling within the protection scope of the present disclosure.

What is claimed is:

1. A method for preparing a substrate with a carrier trapping center, comprising:
providing a semiconductor substrate, a surface of the semiconductor substrate being provided with an insulating layer;
injecting bubbling ions into the semiconductor substrate to form a splitting layer, and injecting modified ions into the insulating layer to form a nano cluster;
providing a supporting substrate;
bonding the supporting substrate to the semiconductor substrate by using the insulating layer as an intermediate layer;
performing a first heat treatment for the bonded substrate such that a splitting layer is formed at the position where the bubbling ions are injected, and causing the semiconductor substrate to split at the position of the splitting layer;
thinning a split surface of the split semiconductor substrate; and
performing a second heat treatment for the thinned semiconductor substrate to consolidate the bonding interface and form the nano cluster at the position where the modified ions are injected.

2. The method for preparing a substrate with a carrier trapping center according to claim 1, wherein through the thinning step, the thickness of the splitting surface is reduced by 10 to 150 nm.

3. The method for preparing a substrate with a carrier trapping center according to claim 1, wherein the second heat treatment further comprises:
performing a first annealing step, wherein the first annealing step is practiced in an oxygen-containing atmosphere, and an oxidation layer is formed on a surface of the substrate through the annealing step, the oxidation layer having a thickness of greater than 40 nm; and
performing a second annealing step upon the first annealing step, wherein a temperature of the second annealing step is higher than that of the first annealing step.

4. The method for preparing a substrate with a carrier trapping center according to claim 3, wherein the first annealing step is practiced in a dry oxygen environment.

5. The method for preparing a substrate with a carrier trapping center according to claim 3, wherein the second annealing step is practiced in an oxygen-free environment.

6. The method for preparing a substrate with a carrier trapping center according to claim 1, wherein the modified ions are derived from one of chemical elements forming the insulating layer, or the modified ions are derived from a congener in chemical elements forming the insulating layer.

7. The method for preparing a substrate with a carrier trapping center according to claim 1, wherein the insulating layer is made from silicon dioxide, and the modified ions are silicon or germanium ions.

8. The method for preparing a substrate with a carrier trapping center according to claim 1, wherein the first heat treatment is performed within a temperature range of 300° C. to 800° C.

9. The method for preparing a substrate with a carrier trapping center according to claim 1, wherein the surface of the supporting substrate for bonding is provided with an oxidation layer.
